(19) United States
(12) Patent Application Publication
(10) Pub. No.: US 2007/0202670 A1
(43) Pub. Date: Aug. 30, 2007

(54) Method for fabricating semiconductor device

(75) Inventor: Chang-Goo Lee, Kyoungki-do (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/637,017

(22) Filed: Dec. 12, 2006

(30) Foreign Application Priority Data
Feb. 28, 2006 (KR) 10-2006-0019671
Sep. 13, 2006 (KR) 10-2006-0088606

(51) Int. Cl. H01L 21/425

(52) U.S. Cl. 438/514

(57) ABSTRACT

A method for fabricating a semiconductor device includes: forming a gate material over a substrate; etching the gate material to form gate patterns each including a portion of the gate material remaining over the substrate; performing a halo ion-implantation process on a portion of the substrate where a bit line contacts; forming sidewall spacers of the gate patterns; and etching the remaining portion of the gate material to expose the substrate using the sidewall spacers as a mask.

### CROSS-REFERENCES TO RELATED APPLICATIONS

The present invention claims priority of Korean patent application numbers 10-2006-0019671 and 10-2006-0088606, filed on Feb. 28, 2006 and Sep. 13, 2006, respectively, which are incorporated by reference in their entirety.

### BACKGROUND OF THE INVENTION

The present invention relates to a method for fabricating a semiconductor device, and more particularly, to a method for fabricating a dynamic random access memory (DRAM) cell applying a halo ion-implantation process.

In a dynamic random access memory (DRAM) device, a technology to improve a refresh property is the most important. Typically, a memory cell may lose data written in a capacitor due to leakage current. A refresh operation can refresh the lost electric charges (e.g., current) by turning on a word line every predetermined period to prevent the data loss. The refresh property depends on a refresh period. The shorter the refresh period of a product, the more power the product consumes. Accordingly, a short refresh period is undesirable. As a method to improve the refresh period, a recess gate formation process and a halo ion-implantation process are suggested.

The halo ion-implantation process prevents the threshold voltage of a cell transistor from being reduced as a channel length is reduced according to the integration of the semiconductor device. Accordingly, through performing the halo ion-implantation process, the threshold voltage is controlled at a desirable level by implanting the same conductive type impurities as a substrate into the substrate where a source/drain junction region is to be formed.

If the halo ion-implantation process is performed on a junction region where the storage node of the cell capacitor contacts, the leakage current property may be degraded. Accordingly, the halo ion-implantation process is applied to the substrate where the bit line contacts a portion where a storage node contact is masked.

FIGS. 1A to 1C are cross-sectional views illustrating a typical halo ion-implantation process. As shown in FIG. 1A, a plurality of gate patterns 15 are formed over a substrate 10 (e.g., a silicon substrate). Each of the gate patterns 15 is formed by sequentially stacking a gate oxide layer 11, a polysilicon layer 12, a tungsten silicide layer 13, and a hard mask 14. A plurality of spacers 16 are formed over sidewalls of the gate patterns 15. The hard mask 15 and the spacers 16 include a nitride-based material. Although not shown, a reference letter D denote a portion where a bit line contacts (i.e., a portion where a first junction region is to be formed) and a reference letter S denotes portions where a plurality of storage nodes contact (i.e., portions where second junction regions are to be formed).

As shown in FIG. 1B, a photoresist layer 19 is formed. Then, the portion where the bit line contacts is selectively subjected to a photo-exposure process and a developing process to remove a predetermined portion of the photoresist layer 19 existing over the portion where the bit line contacts through performing a photo-exposure process and a developing process.

As shown in FIG. 1C, a separate etch back process 20 is performed to remove the photoresist layer 19 remaining over the portions where the bit line contacts. As a result, a photoresist pattern 19A to be used as a mask for a halo ion-implantation process is formed.

Since the portion where the bit line contacts cannot be exposed only by performing the photo-exposure process and the developing process due to the thick photoresist layer 19, the separate etch back process 20 needs to be performed. Practically, during performing the photo-exposure process, the light cannot be transmitted up to a bottom portion of the tungsten silicide layer 13 forming the gate patterns 15.

However, as a design rule is decreased and as a result, an aspect ratio of the gate patterns 15 is gradually increased, it becomes hard to form the photoresist pattern 19A and various limitations are generated. For instance, the photoresist layer 19 may not be formed with equal thickness between the gate patterns 15 due to the increased heights H₁ of the gate patterns 15. As a result, a void (see FIG. 1B) may be produced. If the void is produced, the photoresist pattern 19A cannot perform its role as a mask during the performance of the ion-implantation process.

The photoresist layer 19 remaining between gate patterns 15 may not be completely removed during the performance of the etch back process 20 and thus, residues (e.g., scum) ‘X’ may be generated. The space between the gate patterns 15 may be formed deeply. Also, the etch back process 20 may not be sufficiently performed since not only the portion where the bit line contacts but also the portions where the storage node contact are etched. Accordingly, the etch back process 20 may not completely remove the photoresist layer 19 remaining between the gate patterns 15.

FIGS. 2A, 2B, and 2C are scanning electron microscopy (SEM) micrographs illustrating a typical semiconductor device where a void is produced. In more details, FIG. 2A is a prototype waveform interpolation (PWI) resultant diagram illustrating the void produced in a photoresist layer. FIG. 2B is a SEM micrograph illustrating a top view of the void produced in the photoresist layer. FIG. 2C is a SEM micrograph illustrating a cross-sectional view of the void produced in the photoresist layer.

FIGS. 3A and 3B are SEM micrographs illustrating residues (e.g., scum) produced over a substrate. The scum ‘X’ may obstruct a halo ion-implantation process and act as an impurity in a subsequent process. The scum ‘X’ may not be detected using an inspection tool, thereby causing various limitations.

### SUMMARY OF THE INVENTION

Specific embodiments of the present invention are directed to provide a method for fabricating a semiconductor device capable of reducing a void and a scum during forming a photoresist pattern used for a halo ion-implantation process.

In accordance with one aspect of the present invention, there is provided a method for fabricating a semiconductor device, including: forming a gate material over a substrate; etching the gate material to form gate patterns each including a portion of the gate material remaining over the substrate; performing a halo ion-implantation process on a portion of the substrate where a bit line contacts; forming sidewall spacers of the gate patterns; and etching the remaining portion of the gate material to expose the substrate using the sidewall spacers as a mask.

In accordance with another aspect of the present invention, there is provided a method for fabricating a semiconductor device, including: forming a gate material over a substrate; etching the gate material to form gate patterns each including a portion of the gate material remaining over the substrate; forming an insulation layer over the remaining portion of the gate material; etching the remaining portion of the gate material and a portion of the insulation layer to expose a bit line contact region of the substrate; performing a halo ion-implantation process on the bit line contact region; and etching a further remaining portion of the gate material and another portion of the insulation layer to expose storage node contact regions of the substrate.

### BRIEF DESCRIPTION OF THE DRAWINGS

FIGS. 1A to 1C are cross-sectional views illustrating a typical halo ion-implantation process.

FIG. 2A is a prototype waveform interpolation (PWI) resultant diagram illustrating a void produced in a typical photoresist layer.

FIG. 2B is a micrographic image of scanning electron microscopy (SEM) illustrating a top view of the void shown in FIG. 2A.

FIG. 2C is a micrographic image of SEM illustrating a cross-sectional view of the void shown in FIG. 2A.

FIGS. 3A and 3B are SEM micrographs illustrating residues (e.g., scum) typically produced over a substrate.

FIGS. 4A to 4E are cross-sectional views illustrating a method for fabricating a semiconductor device using a halo ion-implantation process in accordance with an embodiment of the present invention.

FIGS. 5A to 5E are cross-sectional views illustrating a method for fabricating a semiconductor device using a halo ion-implantation process in accordance with another embodiment of the present invention.

### DESCRIPTION OF SPECIFIC EMBODIMENTS

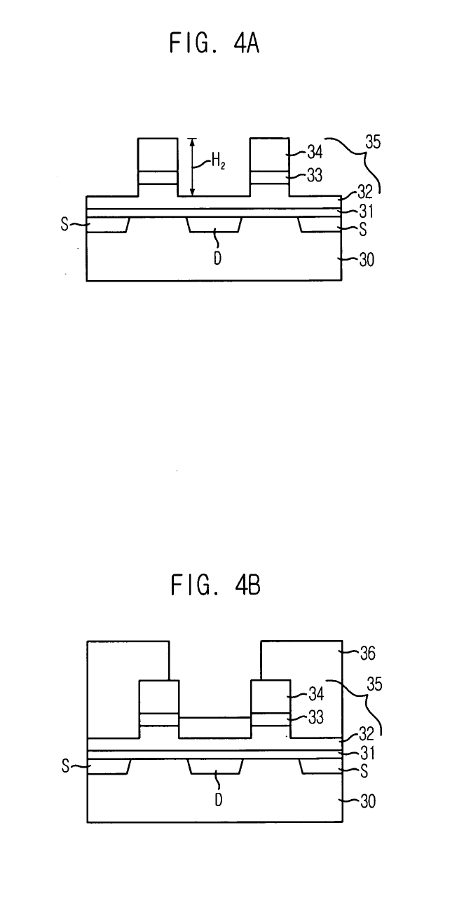

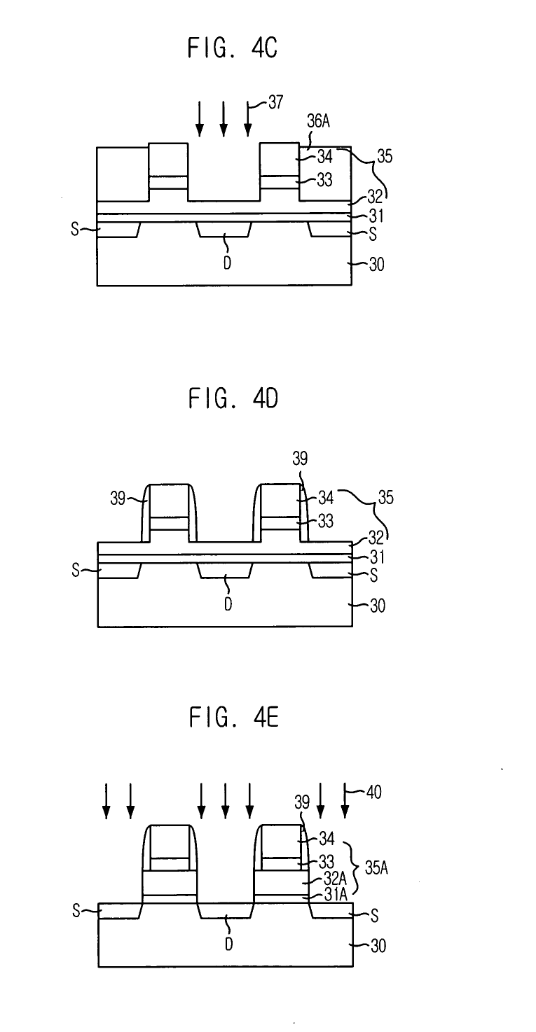

FIGS. 4A to 4E are cross-sectional views illustrating a method for fabricating a semiconductor device in accordance with an embodiment of the present invention. Herein, a dynamic random access memory (DRAM) device is exemplified. As shown in FIG. 4A, a plurality of first gate patterns 35 including a hard mask 34, a patterned tungsten silicide layer 33, a first patterned polysilicon layer 32 are formed over a substrate 30 (e.g., a silicon substrate). In more details, a gate oxide layer 31 is formed and then, a polysilicon layer is formed thereon. The polysilicon layer is formed to a thickness ranging from about 600 Å to about 1,100 Å. Afterwards, a tungsten silicide layer is formed over the polysilicon layer and a hard mask nitride layer is formed over the tungsten silicide layer.

The hard mask nitride layer, the tungsten silicide layer, and the polysilicon layer are etched to a predetermined thickness using a gate mask to obtain the first gate patterns 35. For instance, if the polysilicon layer 32 is formed to a thickness of about 900 Å, an etched portion of the polysilicon layer ranges from about 150 Å to about 500 Å. Making the predetermined thickness of the polysilicon layer remain reduces the generation of voids and scum during the formation of a photoresist pattern (i.e., the photoresist pattern for a subsequent halo ion-implantation mask) since the height H₂ of the first gate patterns 35 is great.

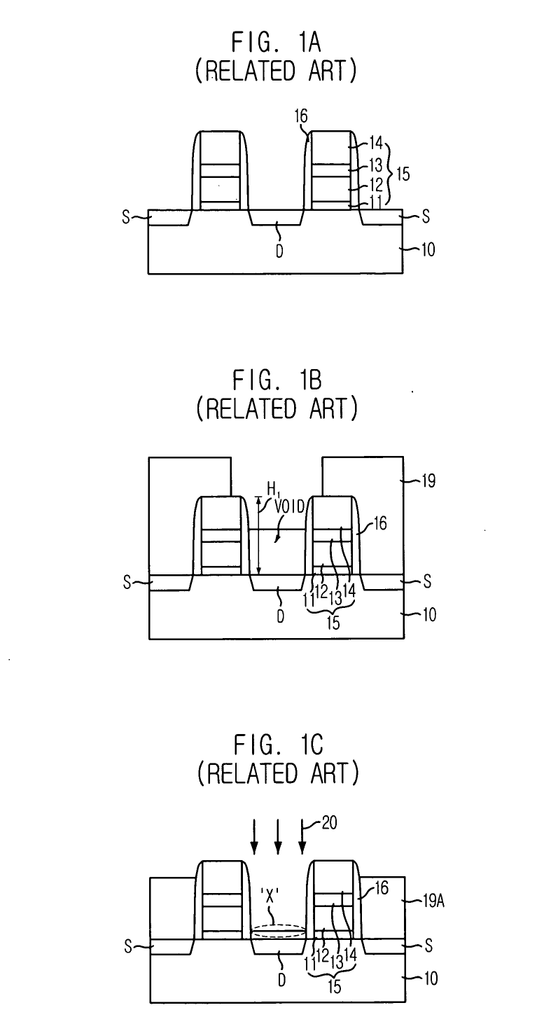

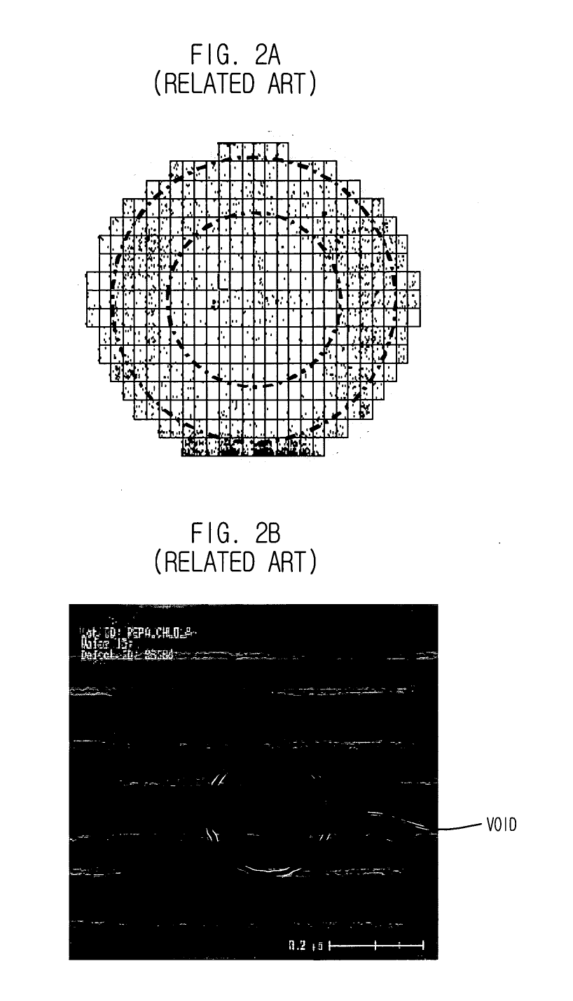

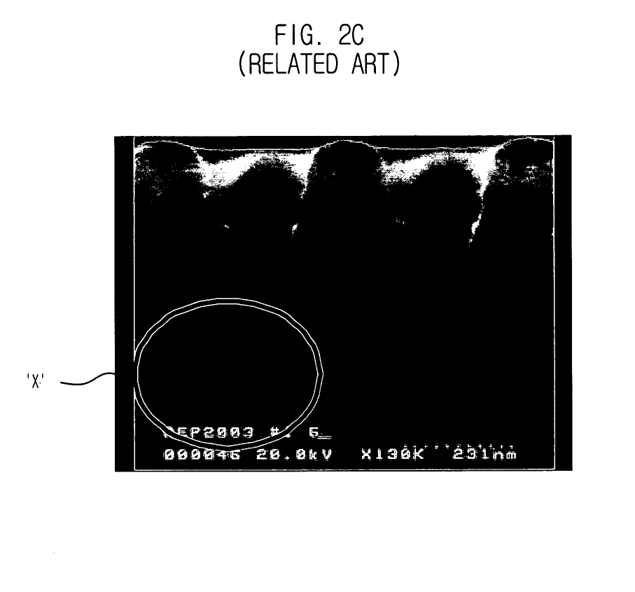

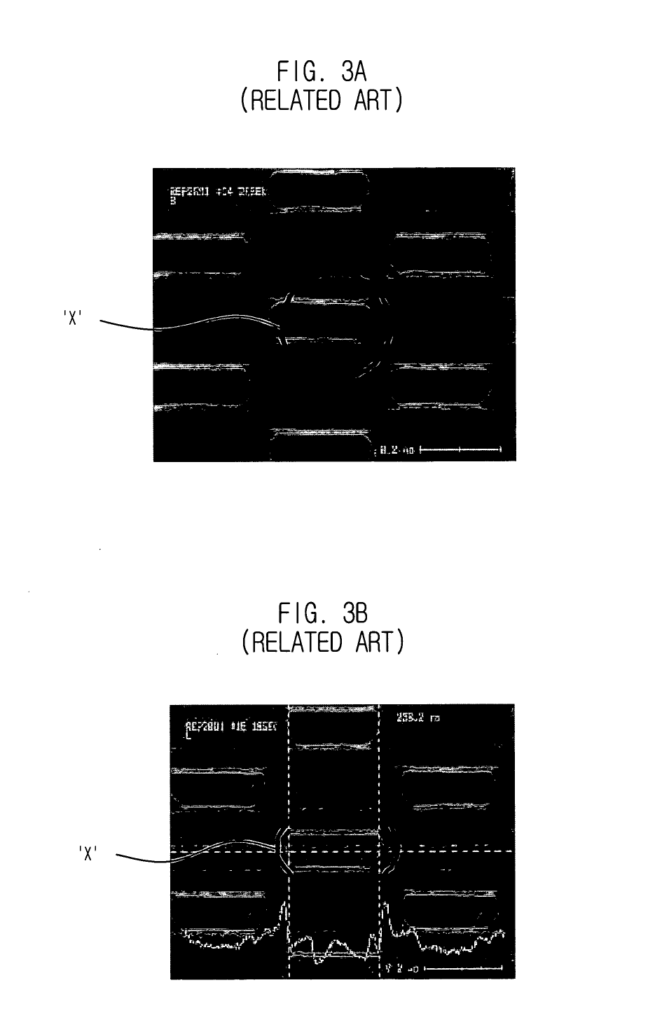

According to the first embodiment of the present invention, the height H₂ of the first gate patterns 35 is reduced at least by a thickness of about 300 Å or by about 500 Å to the maximum (i.e., H₂=H₁−about 500 Å, wherein H₁ denotes the height of the typical gate patterns 15 shown in FIG. 1B). As a result, formation of voids and scum can be reduced. Although not shown, a reference letter D denotes a portion where a bit line contacts (i.e., a region where a first junction region is to be formed), and a reference letter S denotes portions where storage nodes contact (i.e., regions where second junction regions are to be formed).

As shown in FIG. 4B, a first photoresist pattern 36 opening the portion D where the bit line contacts (i.e., a top region where the first junction region is to be formed) and masking the portions S where the storage nodes contact is formed. In more details, a photoresist layer is formed and then, selectively subjected to a photo-exposure process and a developing process to obtain the first photoresist pattern 36.

As shown in FIG. 4C, an etch back process is performed to remove the first photoresist pattern 36 remaining over the portion where the bit line contacts. As a result, the second photoresist pattern 36A is formed. The photoresist layer is formed to a thickness ranging from about 4,500 Å to about 6,500 Å. During the formation of the photoresist layer, the height H₂ of the first gate patterns 35 is much less than the height H₁ of the typical gate patterns 15 (see FIG. 1B) and thus, voids cannot be produced. During the performance of the etch back process, a thickness of the first photoresist pattern 36 existing over the portion where the bit line contacts is also much less than that of the typical photoresist layer 19 (see FIG. 1B) and accordingly, the scum cannot be generated. Particularly, the etch back process may be performed enough to cause damage on a predetermined portion of the first patterned polysilicon layer 32 corresponding to the portion where the bit line contacts to completely remove the first photoresist pattern 36 formed over the portion where the bit line contacts.

A halo ion-implantation process 37 is performed to implant the same conductive type impurities as the substrate 30 into the substrate 30 corresponding to the portion where the bit line contacts (i.e., the region where the first junction region is to be formed). The halo ion-implantation process 37 is performed by implanting boron ions with a dose ranging from about 1×10¹² atoms/cm² to about 5×10¹⁴ atoms/cm² using energy ranging from about 20 KeV to about 80 KeV.

As shown in FIG. 4D, the second photoresist pattern 36A is stripped and then, an insulation layer is formed. Afterwards, an etch back process is performed to form a plurality of first spacers 39 over sidewalls of the first gate patterns 35 which are projected over the first patterned polysilicon layer 32. The first spacers 39 can include a single layer of oxynitride, and a stack structure of an oxynitride layer and an aluminum oxide (Al₂O₃) layer.

As shown in FIG. 4E, an etching process 40 etches the first patterned polysilicon layer 32 and the gate oxide layer 31 using the first spacers 39 and the hard mask 34 as a barrier to obtain the second patterned polysilicon layer 32A and the first patterned gate oxide layer 31A. As a result, a plurality of second gate patterns 35A, each including the hard mask 34, the patterned tungsten silicide layer 33, the second patterned polysilicon layer 32A, and the patterned gate oxide layer 31A, are formed over the substrate 30.

Hereinafter, a plurality of second spacers (not shown) are formed over sidewalls of the second gate patterns 35A according to a method for fabricating a DRAM device. Afterwards, processes for forming a bit line, a capacitor, and a metal interconnection line are performed to complete the DRAM device.

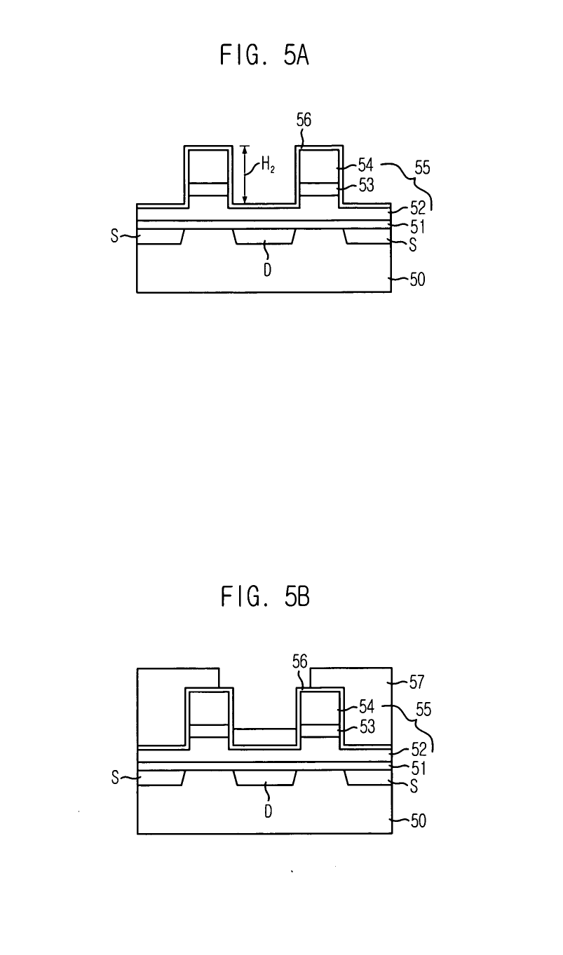

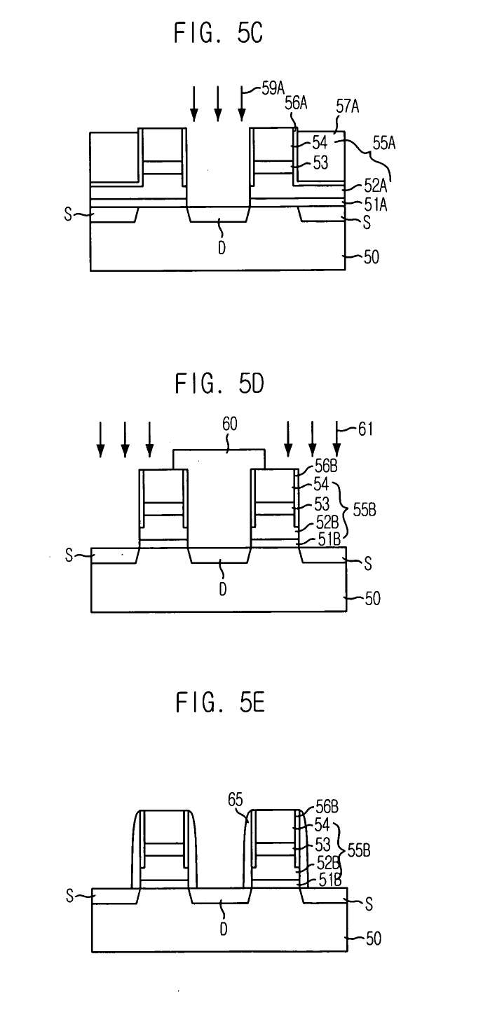

FIGS. 5A to 5E are cross-sectional views illustrating a method for fabricating a semiconductor device in accordance with another embodiment of the present invention. Herein, a dynamic random access memory (DRAM) device is exemplified. As shown in FIG. 5A, a plurality of first gate patterns 55 are formed over a substrate 50. Each of the first gate patterns 55 are formed by stacking a hard mask 54, a patterned tungsten silicide layer 53, and a first patterned polysilicon layer 52. The hard mask 54 includes a nitride-based material. In more detail, a gate oxide layer 51, and a polysilicon layer are formed over the substrate 50. For instance, the polysilicon layer is formed to a thickness ranging from about 600 Å to about 1,100 Å. Afterwards, a tungsten silicide layer is formed over the polysilicon layer and a hard mask nitride layer is formed thereon.

The hard mask nitride layer, the tungsten silicide layer, and the polysilicon layer are etched to a predetermined thickness using a gate mask to obtain the first gate patterns 55. For instance, if the polysilicon layer is formed to a thickness of about 900 Å, an etched thickness of the polysilicon layer ranges from about 150 Å to about 500 Å.

By leaving a predetermined thickness of the polysilicon layer, scum and voids that can be generated during the formation of a photoresist pattern which is a cell halo mask are reduced, since the height H₂ of the first gate pattern 55 is great. That is, according to this embodiment of the present invention, the height (H₂) of the first gate patterns 55 is reduced at least by a thickness of about 300 Å or by about 500 Å to the maximum (i.e., H₂=H₁−about 500 Å, wherein H₁ denotes the height of the typical gate patterns 15 shown in FIG. 1B). As a result, voids and scum can be reduced.

An insulation layer 56 is formed to protect the first gate patterns 55. The insulation layer 56 can include either a single layer of an oxynitride layer, or a stack structure of an oxynitride layer and aluminum oxide (Al₂O₃) layer. Although not shown, a reference letter D denotes a portion where a bit line contacts (i.e., a region where a first junction region is to be formed), and a reference letter S denotes portions where storage nodes contact (i.e., regions where second junction regions are to be formed).

As shown in FIG. 5B, a first photoresist pattern 57 opening the portion where the bit line contacts and masking the portions where the storage nodes contact is formed. In more details, a photoresist layer is formed and then, selectively subjected to a photo-exposure process and a developing process to obtain the first gate photoresist pattern 57.

As shown in FIG. 5C, an etch back process is performed to remove the first photoresist pattern 57 remaining over the portion where the bit line contacts. As a result, a second photoresist pattern 57A is formed. The photoresist layer is formed to a thickness ranging from about 4,500 Å to about 6,500 Å. During forming the photoresist layer, the height H₂ of the first gate patterns 55 is much less than the height H₁ of the typical gate patterns 15 (see FIG. 1B) and accordingly, voids cannot be generated. During the etch back process, the thickness of the first photoresist pattern 57 existing over the portion where the bit line contacts is also much reduced and thus, the scum can be reduced.

The insulation layer 56, the first patterned polysilicon layer 52, and the gate oxide layer 51 are etched to expose the substrate 50 where the bit line contacts. Accordingly, the scum can be completely reduced. Reference numerals 56A, 52A, and 51A respectively denote the patterned insulation layer, the second patterned polysilicon layer, and the first patterned gate oxide layer. A plurality of second gate patterns 55A, each including the hard mask 54, the patterned tungsten silicide layer 53, and the second patterned polysilicon layer 52A, are obtained.

A halo ion-implantation process 59 is performed to implant the same conductive type impurities as the substrate 50 corresponding to the portion where the bit line contacts. The halo ion-implantation process 59 is performed implanting boron ions with a dose ranging from about 1×10¹³ atoms/cm² to about 1×10¹⁴ atoms/cm² and using energy ranging from about 10 KeV to about 50 KeV.

As shown in FIG. 5D, the second photoresist pattern 57A is removed and a third photoresist pattern 60 covering the portion where the bit line contacts and opening the portions where the storage nodes contact is formed. Afterwards, an etching process 61 is performed using the third photoresist pattern 60 as a mask to expose the substrate 50 corresponding to the portions where the storage nodes contact. The third patterned polysilicon layer 52B, and the second patterned gate oxide layer 51B are obtained through performing the etching process 61. As a result, a plurality of third gate patterns 55B, each including the hard mask 54, the patterned tungsten silicide layer 53, the third patterned polysilicon layer 52B, and the second patterned gate oxide layer 51B are formed, and a plurality of first spacers 56B are formed over sidewalls of the third gate patterns 55B.

As shown in FIG. 5E, the third photoresist pattern 60 is stripped and then a plurality of second spacers 65 are formed to protect the sidewalls of the third gate patterns 55B. Hereinafter, processes for forming a capacitor, a bit line, and a metal interconnection line are performed according to a method for forming a DRAM device to complete the DRAM device.

According to the present invention, during fabricating the semiconductor device applying the halo ion-implantation process, the polysilicon layer which forms the gate patterns remains first and then, a photoresist pattern for a cell halo mask is formed. As a result, the generation of voids and scum can be reduced, thereby improving properties of the semiconductor device.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device, comprising:
forming a gate material over a substrate;
etching the gate material to form gate patterns each including a portion of the gate material remaining over the substrate;
performing a halo ion-implantation process on a portion of the substrate where a bit line contacts;
forming sidewall spacers of the gate patterns; and
etching the remaining portion of the gate material to expose the substrate using the sidewall spacers as a mask.

2. The method of claim 1, wherein the performing of the halo ion-implantation process comprises implanting impurities over the portion of the substrate where the bit line contacts using the same conductive impurities as the substrate.

3. The method of claim 2, wherein the impurities for the halo ion-implantation process include boron ions with a dose ranging from about 1×10¹² atoms/cm² to about 5×10¹⁴ atoms/cm² and using energy ranging from about 20 KeV to about 80 KeV.

4. The method of claim 1, wherein the forming of the gate material over the substrate further includes:
forming a gate insulation layer over the substrate;
forming a conductive layer over the gate insulation layer; and
forming a hard mask layer over the conductive layer.

5. The method of claim 4, wherein the conductive layer includes a polysilicon layer and a metal silicide layer.

6. The method of claim 5, wherein the remaining portion of the gate material over the substrate includes a polysilicon layer.

7. The method of claim 5, wherein the polysilicon layer is formed to a thickness ranging from about 600 Å to about 1,100 Å; and about 150 Å to about 500 Å of the polysilicon layer is etched.

8. The method of claim 1, wherein the sidewall spacers include one of an oxynitride layer and a stack structure of an oxynitride layer and an aluminum oxide (Al₂O₃) layer.

9. A method for fabricating a semiconductor device, comprising:
forming a gate material over a substrate;
etching the gate material to form gate patterns each including a portion of the gate material remaining over the substrate;
forming an insulation layer over the remaining portion of the gate material;
etching the remaining portion of the gate material and a portion of the insulation layer to expose a bit line contact region of the substrate;
performing a halo ion-implantation process on the bit line contact region; and
etching a further remaining portion of the gate material and another portion of the insulation layer to expose storage node contact regions of the substrate.

10. The method of claim 9, wherein the performing of the halo ion-implantation process comprises implanting impurities over the bit line contact region of the substrate using substantially the same conductive impurities as the substrate.

11. The method of claim 10, wherein the impurities for the halo ion-implantation process include boron ions with a dose ranging from about 1×10¹³ atoms/cm² to about 1×10¹⁴ atoms/cm² and using energy ranging from about 10 KeV to about 50 KeV.

12. The method of claim 9, wherein the forming of the gate material over the substrate further includes:
forming a gate insulation layer over the substrate;
forming a conductive layer over the gate insulation layer; and
forming a hard mask layer over the conductive layer.

13. The method of claim 12, wherein the conductive layer includes a polysilicon layer and a metal silicide layer.

14. The method of claim 13, wherein the remaining portion of the gate material over the substrate includes a polysilicon layer.

15. The method of claim 14, wherein the polysilicon layer is formed to a thickness ranging from about 600 Å to about 1,100 Å; and about 150 Å to about 500 Å of the polysilicon layer is etched.

16. The method of claim 9, wherein the insulation layer is used as spacers to protect the gate patterns.

17. The method of claim 16, wherein the spacers include one of an oxynitride layer and a stack structure of an oxynitride layer and an aluminum oxide (Al₂O₃) layer.
